(19) United States
(12) Patent Application Publication
(10) Pub. No.: US 2024/0421221 A1
(43) Pub. Date: Dec. 19, 2024

(54) SEMICONDUCTOR DEVICE

(71) Applicant: ROHM CO., LTD., Kyoto-shi (JP)

(72) Inventor: Masaki NAGATA, Kyoto-shi (JP)

(73) Assignee: ROHM CO., LTD., Kyoto-shi (JP)

(21) Appl. No.: 18/818,658

(22) Filed: Aug. 29, 2024

Related U.S. Application Data
(63) Continuation of application No. PCT/JP2023/007142, filed on Feb. 27, 2023.

(30) Foreign Application Priority Data
Mar. 8, 2022 (JP) 2022-035080

(51) Int. Cl. H01L 29/78; H01L 29/423

(52) U.S. Cl. CPC H01L 29/7816; H01L 29/423

(57) ABSTRACT

A semiconductor device includes: a semiconductor layer including a surface; a source region and a drain region arranged on the surface and separated from each other in a first direction as viewed in a thickness-wise direction orthogonal to the surface; a channel region formed on the surface between the source region and the drain region, the channel region being adjacent to the source region; a gate electrode arranged on the channel region with a gate insulating film disposed in between; a trench formed between the source region and the drain region; an insulation film arranged on inner walls of the trench; and an embedded electrode arranged in the trench and surrounded by the insulation film.

### CROSS-REFERENCE TO RELATED APPLICATIONS

The present application is a bypass continuation of International Patent Application No. PCT/JP2023/007142, filed on Feb. 27, 2023, which claims priority to Japanese Patent Application No. 2022-035080 filed in the Japan Patent Office on Mar. 8, 2022, the entire disclosure of these applications are incorporated herein by reference.

### BACKGROUND

The present disclosure relates to a semiconductor device.

A lateral semiconductor device including a drain region and a source region formed on a main surface of a substrate is known as a typical power semiconductor device (for example, refer to Japanese Laid-Open Patent Publication No. 2000-286417).

### BRIEF DESCRIPTION OF DRAWINGS

FIG. 1 is a schematic plan view showing an example of a semiconductor device in accordance with an embodiment.

FIG. 2 is a cross-sectional view of the semiconductor device shown in FIG. 1 taken along line 2-2.

FIG. 3 is a cross-sectional view of the semiconductor device shown in FIG. 1 taken along line 3-3.

FIG. 4 is a schematic cross-sectional view showing an example of a modified semiconductor device.

FIG. 5 is a schematic plan view showing an example of a modified semiconductor device.

FIG. 6 is a schematic plan view showing an example of a modified semiconductor device.

FIG. 7 is a schematic plan view showing an example of a modified semiconductor device.

FIG. 8 is a schematic plan view showing an example of a modified semiconductor device.

FIG. 9 is a schematic plan view showing an example of a modified semiconductor device.

FIG. 10 is a schematic plan view showing an example of a modified semiconductor device.

FIG. 11 is a schematic plan view showing an example of a modified semiconductor device.

FIG. 12 is a schematic plan view showing an example of a modified semiconductor device.

FIG. 13 is a schematic plan view showing an example of a modified semiconductor device.

FIG. 14 is a schematic cross-sectional view showing an example of a modified semiconductor device.

FIG. 15 is a schematic cross-sectional view showing an example of a modified semiconductor device.

### DETAILED DESCRIPTION

An embodiment of a semiconductor device in accordance with the present disclosure will now be described with reference to the drawings.

Elements in the drawings are illustrated for simplicity and clarity and not necessarily drawn to scale. To facilitate understanding, hatching lines may not be shown in the cross-sectional drawings. The accompanying drawings merely illustrate exemplary embodiments in accordance with the present disclosure and are not intended to limit the present disclosure. Terms such as “first”, “second”, and “third” in this disclosure are used to distinguish subjects and not used for ordinal purposes.

This detailed description includes exemplary embodiments of methods, apparatuses, and/or systems in accordance with the present disclosure. This detailed description is illustrative and not intended to limit embodiments of the present disclosure or the application and use of the embodiments.

### Configuration of Semiconductor Device

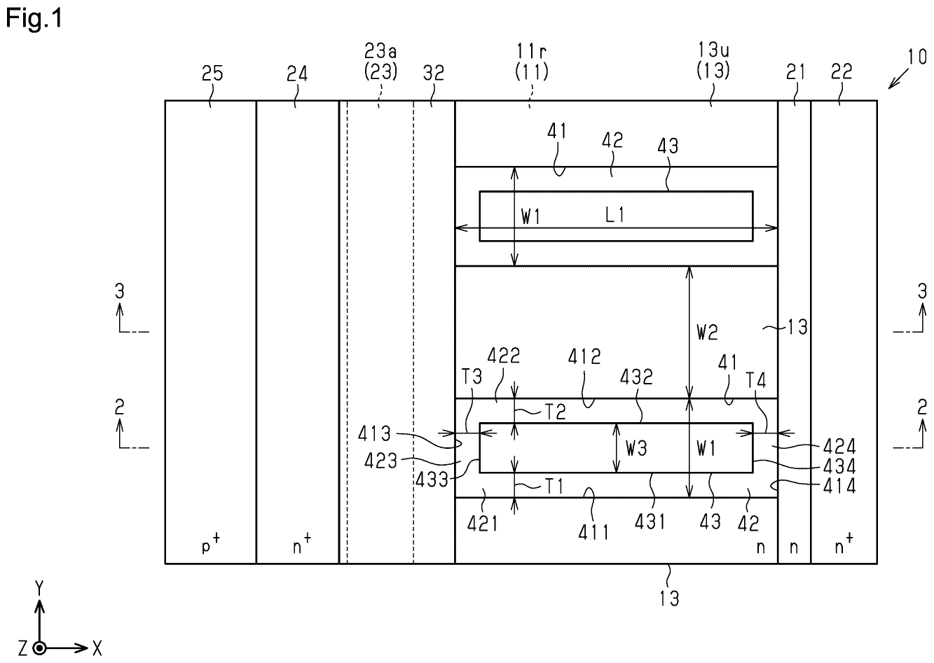

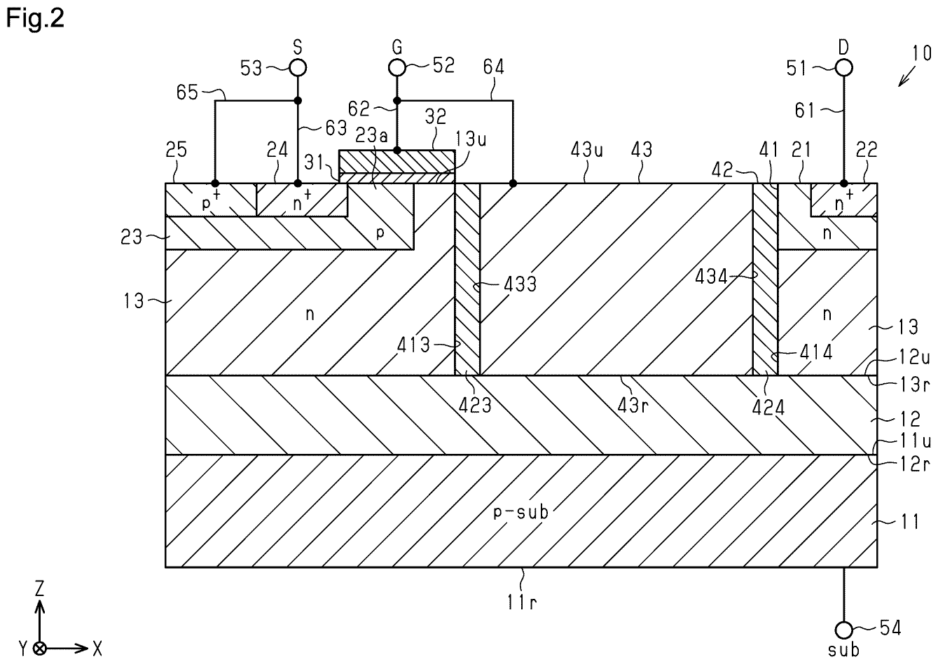

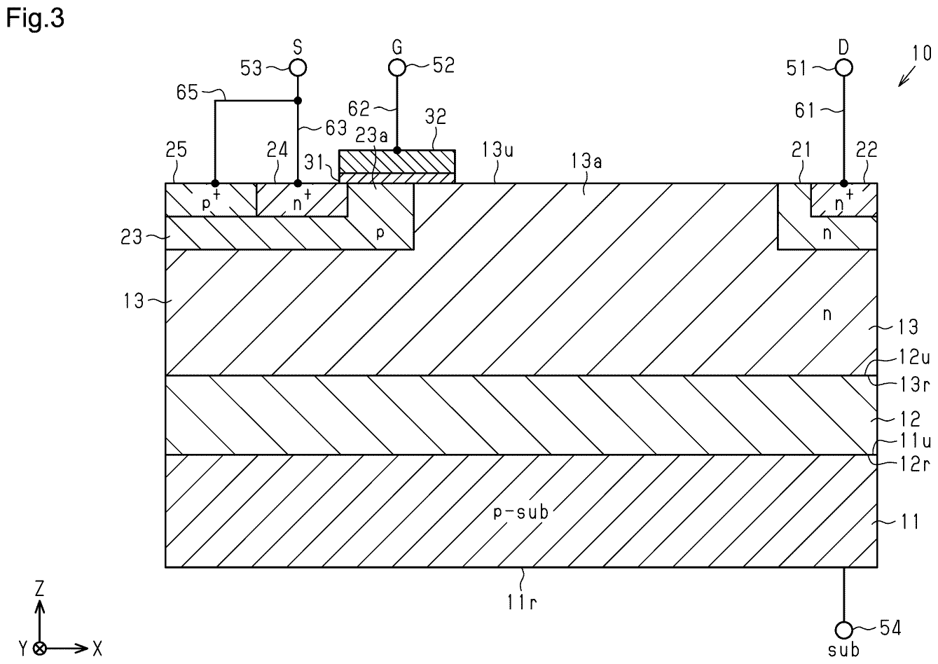

FIG. 1 is a schematic plan view showing an example of a semiconductor device in accordance with the present embodiment. FIG. 2 is a cross-sectional view of the semiconductor device shown in FIG. 1 taken along line 2-2. FIG. 3 is a cross-sectional view of the semiconductor device shown in FIG. 1 taken along line 3-3.

As shown in FIGS. 2 and 3, a semiconductor device 10 may include a semiconductor substrate 11, an insulation layer 12, and a semiconductor layer 13.

The semiconductor substrate 11 may be a silicon (Si) substrate. The semiconductor substrate 11 includes a first surface 11u and a second surface 11r located at a side opposite to the first surface 11u. The semiconductor substrate 11 may be a p-substrate (denoted by “p-sub”) containing a p-type impurity. The semiconductor substrate 11 may be a substrate formed from, for example, silicon carbide (SiC) or the like.

The insulation layer 12 is arranged on the first surface 11u of the semiconductor substrate 11. The insulation layer 12 includes a first surface 12u and a second surface 12r located at a side opposite to the first surface 12u. In the example shown in FIGS. 2 and 3, the second surface 12r of the insulation layer 12 is in contact with the first surface 11u of the semiconductor substrate 11. The insulation layer 12 is formed from a material including, for example, SiO₂. The insulation layer 12 may be formed by oxidation of a surface of the semiconductor substrate 11. The insulation layer 12 may be formed by, for example, a buried oxide (BOX) film.

The semiconductor layer 13 is formed on the first surface 12u of the insulation layer 12. The semiconductor layer 13 includes a first surface 13u and a second surface 13r located at a side opposite to the first surface 13u. The first surface 13u corresponds to “surface” of the semiconductor layer 13. In the example shown in FIGS. 2 and 3, the second surface 13r of the semiconductor layer 13 is in contact with the first surface 12u of the insulation layer 12. The second surface 13r of the semiconductor layer 13 covers, for example, the entire first surface 12u of the insulation layer 12.

The semiconductor layer 13 may be formed by, for example, an epitaxial layer. The semiconductor layer 13 is formed from a material including Si. The semiconductor layer 13 contains an n-type impurity. The semiconductor layer 13 may be, for example, laminated on the semiconductor substrate 11 with the insulation layer 12 located in between. Such a semiconductor device 10 has a silicon-on-insulator (SOI) structure in which the semiconductor layer 13 is formed on the semiconductor substrate 11 with the insulation layer 12 disposed in between.

A direction orthogonal to the first surface 13u of the semiconductor layer 13 is the thickness-wise direction of the semiconductor device 10. This thickness-wise direction will be referred to as the Z-direction. Two directions that are orthogonal to each other and to the Z-direction will be referred to as the X-direction and the Y-direction. The X-direction and the Y-direction are parallel to the first surface 13u of the semiconductor layer 13. The X-direction corresponds to “first direction”. The Y-direction corresponds to “second direction”.

### Source Region, Drain Region, and Gate Electrode

As shown in FIGS. 1 to 3, the semiconductor device 10 includes a buffer region 21, a drain region 22, a body region 23, a source region 24, and a contact region 25.

The buffer region 21 is formed on the first surface 13u of the semiconductor layer 13. The buffer region 21 is an n-type region containing an n-type impurity. As shown in FIG. 1, the body region 23 extends in the Y-direction as viewed in the Z-direction, which is orthogonal to the first surface 13u of the semiconductor layer 13.

As shown in FIGS. 2 and 3, the drain region 22 is formed in the buffer region 21. The drain region 22 contains an n-type impurity. The drain region 22 has a higher impurity concentration than the body region 23. The drain region 22 is an n⁺-type region. As shown in FIG. 1, the drain region 22 extends in the Y-direction as viewed in the Z-direction.

As shown in FIGS. 2 and 3, the body region 23 is formed on the first surface 13u of the semiconductor layer 13. The body region 23 is separated from the buffer region 21 in the X-direction. The body region 23 is a p-type region containing a p-type impurity. As shown in FIG. 1, the body region 23 extends in the Y-direction as viewed in the Z-direction.

As shown in FIGS. 2 and 3, the source region 24 is formed in the body region 23. The source region 24 contains an n-type impurity. The source region 24 may have, for example, the same impurity concentration as the drain region 22. The source region 24 is an n⁺-type region. As shown in FIG. 1, the source region 24 extends in the Y-direction as viewed in the Z-direction.

As shown in FIGS. 2 and 3, the contact region 25 is formed in the body region 23. The contact region 25 and the drain region 22 are located at opposite sides of the source region 24. The contact region 25 is arranged to contact the source region 24. The contact region 25 contains a p-type impurity. The contact region 25 has, for example, a higher impurity concentration than the body region 23. The contact region 25 is a p⁺-type region. As shown in FIG. 1, the contact region 25 extends in the Y-direction as viewed in the Z-direction.

As shown in FIG. 3, the semiconductor layer 13 located between the buffer region 21 and the body region 23 acts as a drift region 13a.

As shown in FIGS. 2 and 3, a gate electrode 32 is arranged on the first surface 13u of the semiconductor layer 13 with a gate insulating film 31 disposed in between. As shown in FIG. 1, the gate electrode 32 extends in the Y-direction. As shown in FIGS. 2 and 3, the gate insulating film 31 and the gate electrode 32 cover the body region 23 located between the source region 24 and the semiconductor layer 13 in the X-direction. Also, the gate insulating film 31 and the gate electrode 32 cover part of the source region 24 adjacent to the body region 23. Further, the gate insulating film 31 and the gate electrode 32 cover part of the semiconductor layer 13 adjacent to the body region 23. The gate insulating film 31 is formed from an insulation material, such as silicon oxide (SiO₂), silicon nitride (SiN), or the like. The gate electrode 32 is formed from a material including, for example, a conductive polysilicon or the like.

As shown in FIGS. 2 and 3, a portion of the body region 23 that faces the gate electrode 32 with the gate insulating film 31 disposed in between acts as a channel region 23a where an inversion layer (channel) is formed.

### Trench and Embedded Electrode

As shown in FIGS. 1 and 2, the semiconductor device 10 includes a trench 41, an insulation film 42, and an embedded electrode 43.

The trench 41 is formed between the source region 24 and the drain region 22. The semiconductor device 10 of the present embodiment includes more than one trench 41. As viewed in the Z-direction, each trench 41 is formed between the gate electrode 32 and the buffer region 21. The trenches 41 extend in the X-direction as viewed in the Z-direction. As shown in FIG. 1, the trenches 41 are arranged next to one another in the Y-direction. In other words, the trenches 41 are arranged next to one another in the Y-direction, which is orthogonal to the X-direction in which the trenches 41 extend. Accordingly, as viewed in the Z-direction, the trenches 41 and the semiconductor layers 13 (drift regions 13a) are alternately arranged in the Y-direction, which is orthogonal to the X-direction in which the trenches 41 extend.

Each trench 41 has a width W1 in the Y-direction that is less than a length L1 of the trench 41 in the X-direction. The trenches 41 are arranged at an interval W2 in the Y-direction. The interval W2 between two trenches 41 is, for example, greater than the width W1 of the trench 41 in the Y-direction.

As shown in FIG. 2, the trench 41 extends through the semiconductor layer 13 from the first surface 13u of the semiconductor layer 13 to the second surface 13r of the semiconductor layer 13. The second surface 13r of the semiconductor layer 13 is in contact with the first surface 12u of the insulation layer 12. Thus, the trench 41 extends through the semiconductor layer 13 from the first surface 13u of the semiconductor layer 13 to the insulation layer 12.

As shown in FIG. 1, as viewed in the Z-direction, an end of the trench 41 located toward the source region 24 is in the same position as an end of the gate electrode 32 located toward the drain region 22. In other words, the end of the trench 41 located toward the source region 24 coincides with the end of the gate electrode 32 located toward the drain region 22. In the present embodiment, as viewed in the Z-direction, an end of the trench 41 located toward the drain region 22 is in contact with the buffer region 21. In other words, the end of the trench 41 located toward the drain region 22 coincides with an end of the buffer region 21 located toward the source region 24.

As shown in FIG. 1, the trench 41 includes inner walls 411, 412, 413, and 414. The first inner wall 411 and the second inner wall 412 extend in the X-direction. The first inner wall 411 faces the second inner wall 412 in the Y-direction. The third inner wall 413 and the fourth inner wall 414 extend in the Y-direction. The third inner wall 413 faces the fourth inner wall 414 in the X-direction.

The insulation film 42 covers the inner walls 411 to 414 of the trench 41. The insulation film 42 includes a first insulation film 421 that covers the first inner wall 411, a second insulation film 422 that covers the second inner wall 412, a third insulation film 423 that covers the third inner wall 413, and a fourth insulation film 424 that covers the fourth inner wall 414. The insulation films 421 to 424 are each in contact with a corresponding one of the inner walls 411 to 414. The insulation film 42 is formed from, for example, silicon oxide, or the like.

The embedded electrode 43 is formed in the trench 41. As shown in FIGS. 1 and 2, the embedded electrode 43 includes a first surface 43u, a second surface 43r, and side surfaces 431, 432, 433, and 434. The first surface 43u faces the same direction as the first surface 13u of the semiconductor layer 13. The second surface 43r faces a direction opposite to the first surface 43u. In the present embodiment, the second surface 43r of the embedded electrode 43 is in contact with the first surface 12u of the insulation layer 12. The first side surface 431 and the second side surface 432 face opposite sides in the Y direction. The third side surface 433 and the fourth side surface 434 face opposite sides in the X-direction. The side surfaces 431 to 434 are each in contact with a corresponding one of the insulation films 421 to 424. The embedded electrode 43 is formed from a material including, for example, a conductive polysilicon or the like. The embedded electrode 43 may be formed from a material including tungsten (W) or the like.

As shown in FIG. 1, in the present embodiment, a film thickness T1 of the first insulation film 421 is equal to a film thickness T2 of the second insulation film 422. Further, a film thickness T3 of the third insulation film 423 is equal to a film thickness T4 of the fourth insulation film 424. The film thicknesses T1 and T2 each correspond to “first film thickness”. The film thicknesses T3 and T4 each correspond to “second film thickness”. In the present embodiment, the film thicknesses T1 to T4 of the insulation films 421 to 424 are identical.

As described above, the embedded electrode 43 is arranged in each trench 41. Accordingly, as viewed in the Z-direction, the trenches 41, the embedded electrodes 43, and the semiconductor layers 13 (drift regions 13a) are alternately arranged in the Y-direction.

### Interconnection and Terminal

As shown in FIGS. 2 and 3, the semiconductor device 10 includes terminals 51, 52, 53, and 54. The drain region 22 is connected to the terminal (D) 51 by an interconnecting member 61. The gate electrode 32 is connected to the terminal (G) 52 by an interconnecting member 62. The embedded electrode 43 is connected to the gate electrode 32 by an interconnecting member 64. The source region 24 is connected to the terminal(S) 53 by an interconnecting member 63. The source region 24 is connected to the contact region 25 by an interconnecting member 65. The terminals 51 to 53 may each be, for example, a pad (electrode) configured to allow for connection of a wire or the like to the semiconductor device 10. In the semiconductor device 10, the interconnecting members 61 to 65 may each be a conductor formed in one or more interconnection layers. The conductor is formed from a material including, for example, a conductive material such as aluminum (Al), copper (Cu), or the like. The semiconductor substrate 11 is connected to the terminal (sub) 54. The terminal 54 may be, for example, a pad (electrode) configured to allow for connection of the semiconductor device 10 to a die pad or the like.

### Operation

The operation of the semiconductor device 10 will now be described.

In the semiconductor device 10, a voltage is applied between the drain region 22 and the source region 24. In the semiconductor device 10, a gate voltage applied to the gate electrode 32 controls the ON/OFF states of the current flowing between the drain region 22 and the source region 24.

When the gate electrode 32 receives a gate voltage greater than or equal to a threshold voltage, a channel (inversion layer) is formed in the body region 23 (channel region 23a) that faces the gate electrode 32 in the Z-direction. Electrons flow through the inversion layer from the source region 24 to the semiconductor layer 13. The electric field between the drain region 22 and the source region 24 shifts the semiconductor device 10 to an ON state in which a drift current flows from the drain region 22 to the source region 24.

The embedded electrode 43 is connected to the gate electrode 32. Thus, the above gate voltage is applied to the embedded electrode 43. This gate voltage accumulates electrons in a portion of the semiconductor layer 13 that faces the embedded electrode 43 with the insulation film 42 located in between. Such accumulation of electrons has substantially the same advantage as increasing the impurity concentration of the semiconductor layer 13 (drift region 13a) around the trench 41, in which the embedded electrode 43 is arranged. This decreases the ON-resistance of the semiconductor device 10.

When the gate electrode 32 receives a gate voltage less than or equal to the threshold voltage, such as a voltage equivalent to that of the source region 24, the p-n junction between the p-type body region 23 and the n-type semiconductor layer 13 is reverse-biased by the voltage between the drain region 22 and the source region 24. This expands a depletion layer from the p-n junction. Further, when the gate voltage is applied to the embedded electrode 43 connected to the gate electrode 32, the depletion layer expands in a portion of the semiconductor layer 13 that faces the embedded electrode 43 with the insulation film 42 located in between. In this manner, the semiconductor device 10 has relatively high breakdown voltage characteristics.

### Advantages

As described above, the present embodiment has the following advantages.

(1) The semiconductor device 10 includes the semiconductor layer 13, the source region 24, and the drain region 22. The semiconductor layer 13 includes the first surface 13u. The source region 24 and the drain region 22 are arranged on the first surface 13u and separated from each other in the X-direction (first direction) as viewed in the Z-direction (thickness-wise direction) orthogonal to the first surface 13u. The semiconductor device 10 includes the channel region 23a and the gate electrode 32. The channel region 23a is formed on the first surface 13u between the source region 24 and the drain region 22. The channel region 23a is adjacent to the source region 24. The gate electrode 32 is arranged on the channel region 23a with the gate insulating film 31 disposed in between. The semiconductor device 10 further includes the trench 41, the insulation film 42, and the embedded electrode 43. The trench 41 is formed between the source region 24 and the drain region 22. The insulation film 42 is arranged on the inner walls 411 to 414 of the trench 41. The embedded electrode 43 is arranged in the trench 41 and surrounded by the insulation film 42.

When the gate electrode 32 receives a gate voltage greater than or equal to a threshold voltage, a channel (inversion layer) is formed in the body region 23 (channel region 23a) that faces the gate electrode 32 in the Z-direction. Electrons flow through the inversion layer from the source region 24 to the semiconductor layer 13. The electric field between the drain region 22 and the source region 24 shifts the semiconductor device 10 to an ON state in which a drift current flows from the drain region 22 to the source region 24.

The embedded electrode 43 is connected to the gate electrode 32. Thus, the above gate voltage is applied to the embedded electrode 43. This gate voltage accumulates electrons in a portion of the semiconductor layer 13 that faces the embedded electrode 43 with the insulation film 42 located in between. Such accumulation of electrons has substantially the same advantage as increasing the impurity concentration of the semiconductor layer 13 (drift region 13a) around the trench 41, in which the embedded electrode 43 is arranged. This decreases the ON-resistance of the semiconductor device 10.

(2) When the gate electrode 32 receives a gate voltage less than or equal to the threshold voltage, such as a voltage equivalent to that of the source region 24, the p-n junction between the p-type body region 23 and the n-type semiconductor layer 13 is reverse-biased by the voltage between the drain region 22 and the source region 24. This expands a depletion layer from the p-n junction. Further, when the gate voltage is applied to the embedded electrode 43 connected to the gate electrode 32, the depletion layer expands in a portion of the semiconductor layer 13 that faces the embedded electrode 43 with the insulation film 42 located in between. In this manner, the semiconductor device 10 has relatively high breakdown voltage characteristics. This improves the breakdown voltage of the semiconductor device 10.

### MODIFIED EXAMPLES

The above embodiment may be modified as described below. The above embodiment and the modified examples described below may be combined as long as there is no technical contradiction. In the modified examples described hereafter, same reference numerals are given to those components that are the same as the corresponding components of the above embodiment. Such components will not be described in detail.

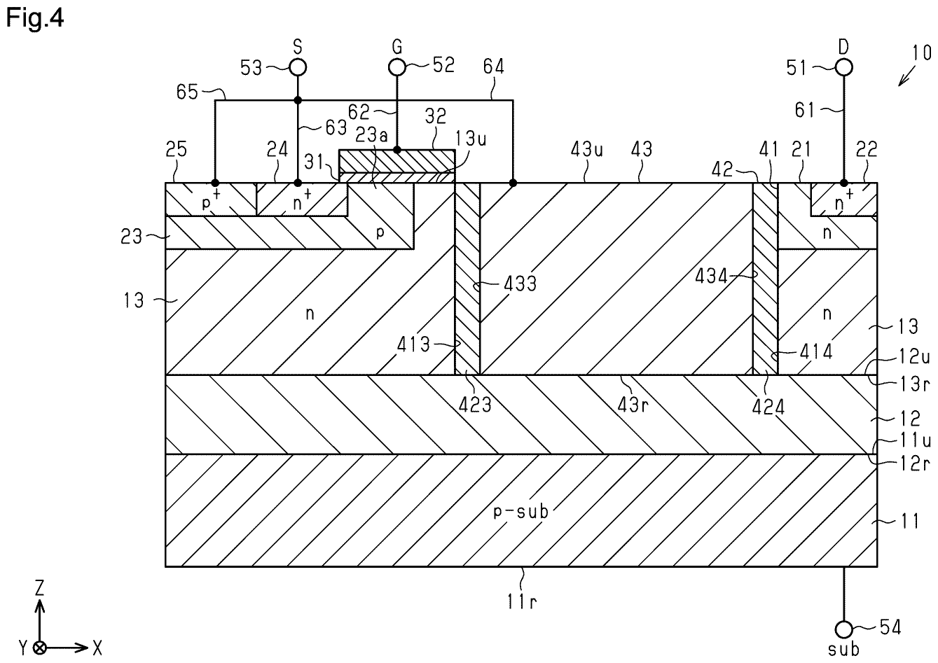

In contrast to the above embodiment, as shown in FIG. 4, the embedded electrode 43 may be connected to the source region 24. In this case, a depletion layer is formed in the same manner as when a gate voltage lower than or equal to a threshold voltage is applied to the gate electrode 32. This improves the breakdown voltage.

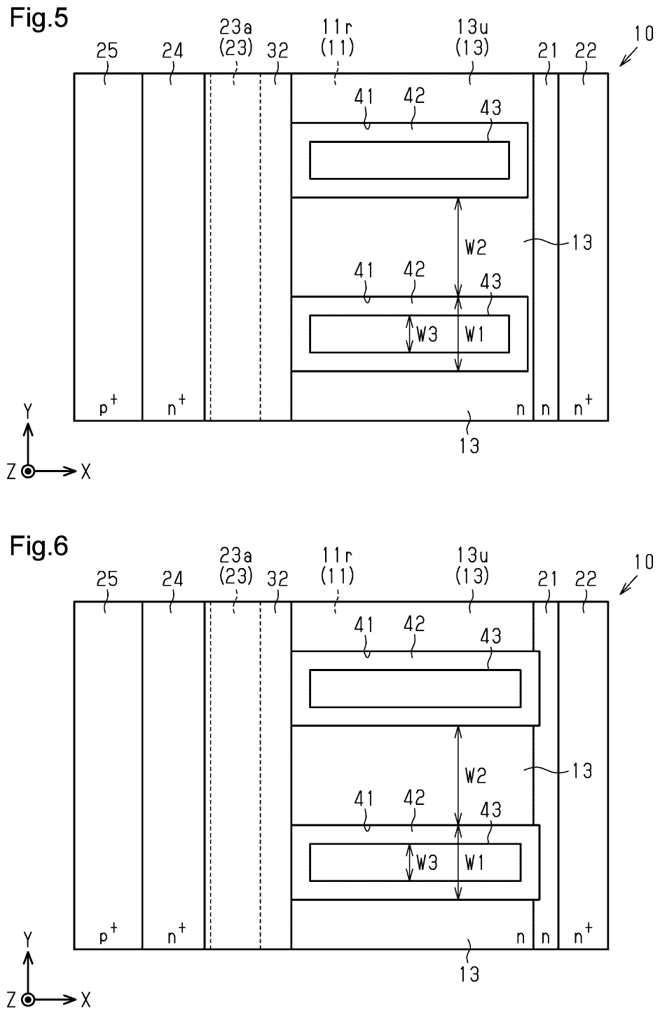

As shown in FIG. 5, the trench 41 may be formed so that the end of the trench 41 located toward the drain region 22 is separated from the buffer region 21 as viewed in the Z-direction.

As shown in FIG. 6, the trench 41 may be formed so that the end of the trench 41 located toward the drain region 22 overlaps the buffer region 21 as viewed in the Y-direction.

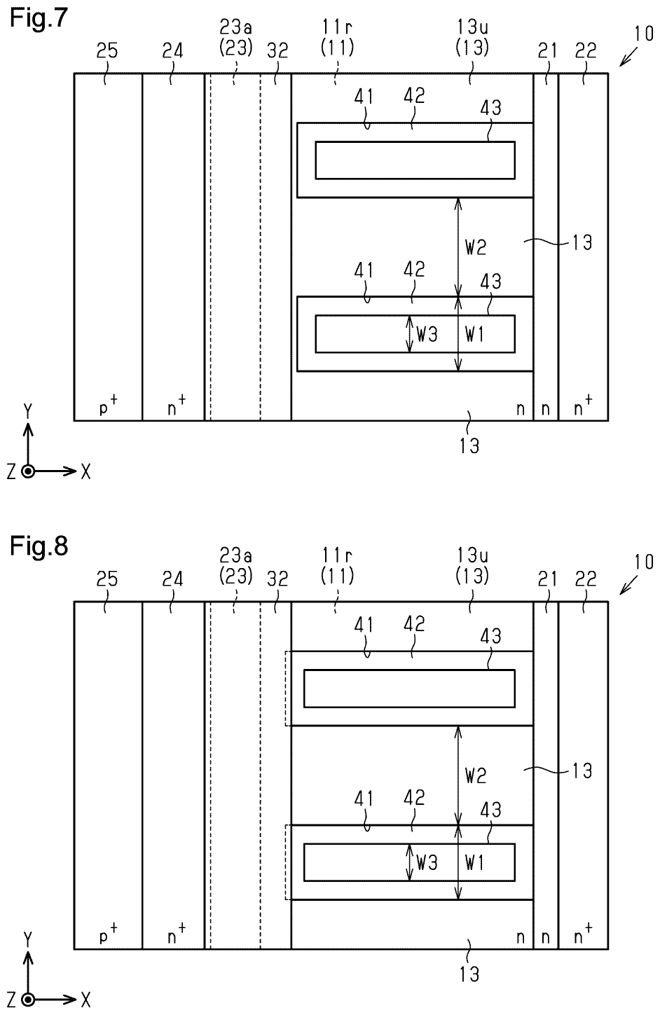

As shown in FIG. 7, the trench 41 may be formed so that the end of the trench 41 located toward the source region 24 is separated from the gate electrode 32 as viewed in the Z-direction. In this case, the insulation film 42 may be formed so that the film thickness T3 of the third insulation film 423 differs from the film thickness T4 of the fourth insulation film 424.

As shown in FIG. 8, the trench 41 may be formed so that the end of the trench 41 located toward the source region 24 overlaps the gate electrode 32 as viewed in the Z-direction. In this case, the insulation film 42 may be formed so that the film thickness T3 of the third insulation film 423 differs from the film thickness T4 of the fourth insulation film 424.

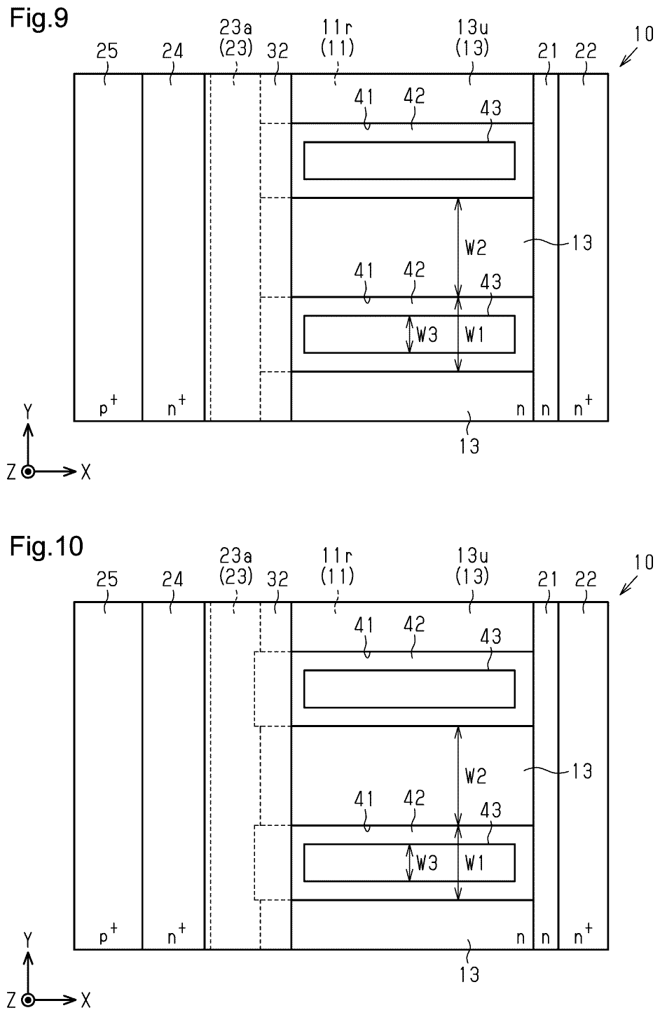

As shown in FIG. 9, the trench 41 may be formed so that the end of the trench 41 located toward the source region 24 is in contact with the body region 23 as viewed in the Z-direction. In this case, the insulation film 42 may be formed so that the film thickness T3 of the third insulation film 423 differs from the film thickness T4 of the fourth insulation film 424. Preferably, the embedded electrode 43 does not overlap the gate electrode 32 as viewed in the Z-direction.

As shown in FIG. 10, the trench 41 may be formed so that the end of trench 41 located toward the source region 24 overlaps the body region 23 as viewed in the Y-direction. In this case, the insulation film 42 may be formed so that the film thickness T3 of the third insulation film 423 differs from the film thickness T4 of the fourth insulation film 424. Preferably, the embedded electrode 43 does not overlap the gate electrode 32 as viewed in the Z-direction.

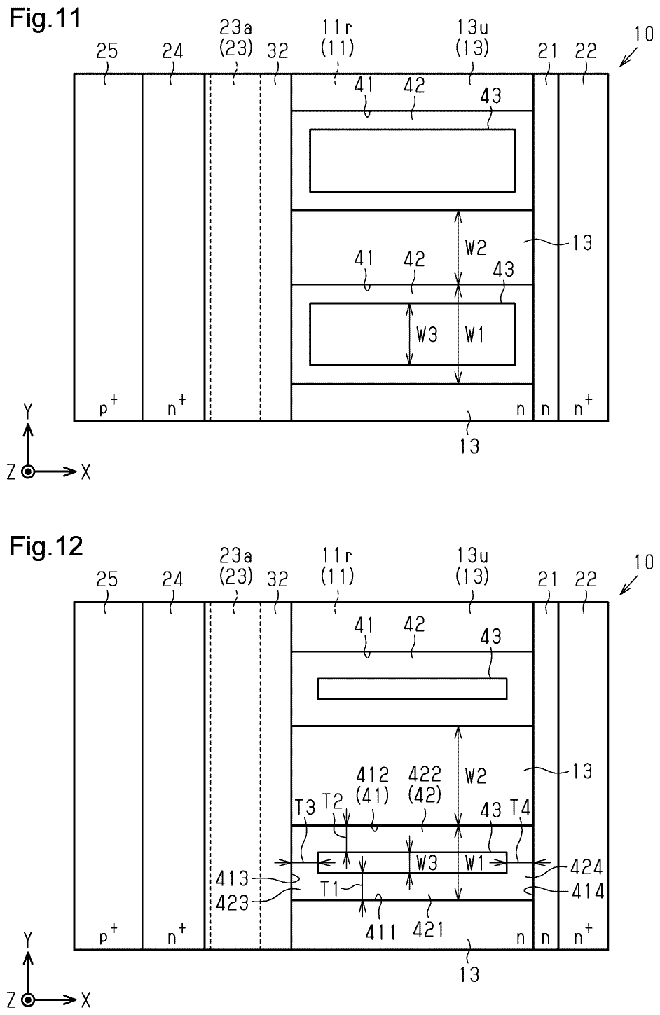

As shown in FIG. 11, as viewed in the Z-direction, the trench 41 may be formed so that the width W1 of the trench 41 is greater than the interval W2 between two trenches 41 adjacent to each other in the Y-direction. Alternatively, the trench 41 may be formed so that the width W1 of the trench 41 is equal to the interval W2 between two trenches 41 adjacent to each other in the Y-direction.

As shown in FIG. 12, as viewed in the Z-direction, the film thicknesses T1 to T4 of the insulation film 42 (421 to 424), which covers the inner walls 411 to 414 of the trench 41, may be changed. The film thicknesses T1 to T4 may each be, for example, greater than a width W3 of the embedded electrode 43.

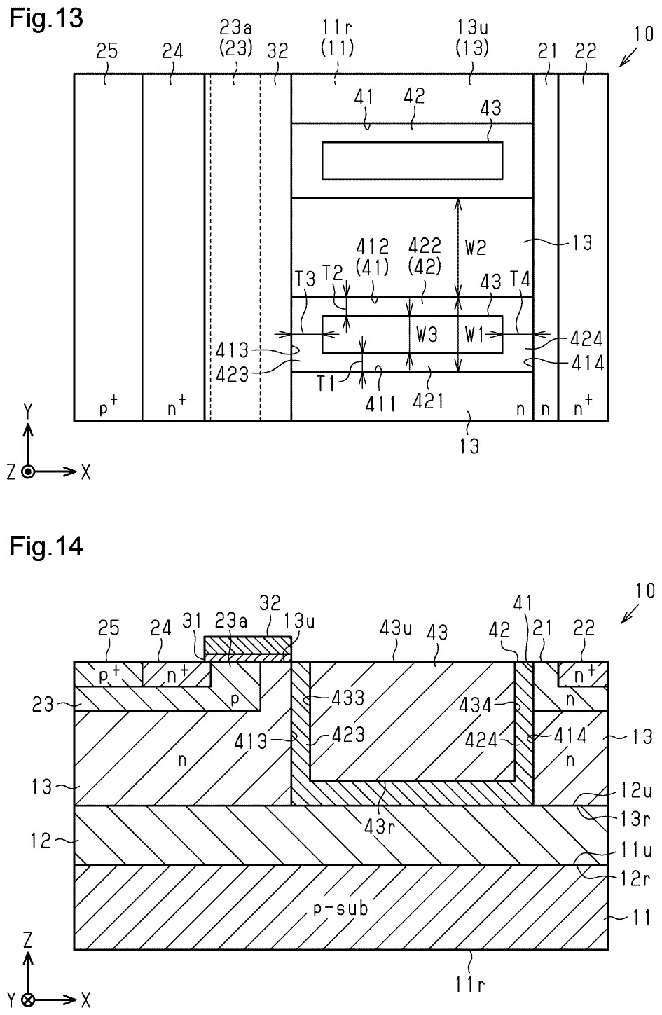

As shown in FIG. 13, the insulation film 42 may be formed so that each of the film thickness T1 of the first insulation film 421 and the film thickness T2 of the second insulation film 422 is less than each of the film thickness T3 of the third insulation film 423 and the film thickness T4 of the fourth insulation film 424. Alternatively, the insulation film 42 may be formed so that each of the film thickness T1 of the first insulation film 421 and the film thickness T2 of the second insulation film 422 is greater than each of the film thickness T3 of the third insulation film 423 and the film thickness T4 of the fourth insulation film 424.

As shown in FIG. 14, the embedded electrode 43 may be separated from the insulation layer 12. The insulation film 42 is located between the second surface 43r of the embedded electrode 43 and the insulation layer 12.

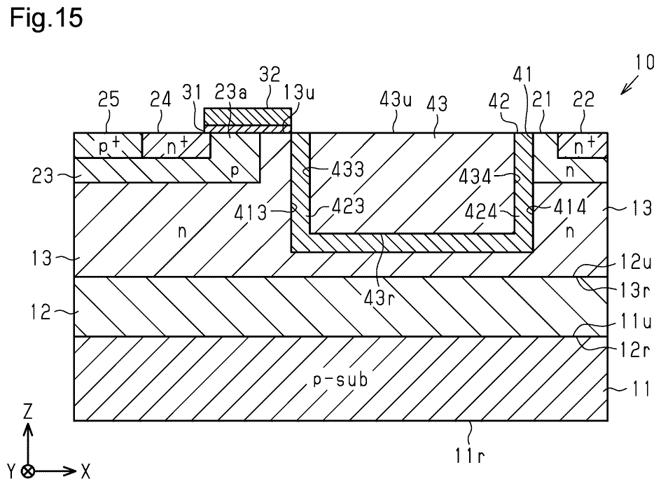

As shown in FIG. 15, the trench 41 may be separated from the insulation layer 12 in the Z-direction. In other words, the trench 41 does not have to extend through the semiconductor layer 13.

The buffer region 21 may be omitted.

The embedded electrode 43 may be connected to a terminal arranged on the semiconductor device. The terminal may be a pad (electrode) configured to allow for connection of a wire or the like to the semiconductor device.

In this specification, the term “on” includes the meaning of “above” in addition to the meaning of “on” unless otherwise indicated in the context. Accordingly, the phrase “first layer formed on second layer” may mean that the first layer is formed directly contacting the second layer in one embodiment and that the first layer is located above the second layer without contacting the second layer in another embodiment. Thus, the term “on” will also allow for a structure in which another layer is formed between the first layer and the second layer.

The Z-axis direction as referred to in this specification does not necessarily have to be the vertical direction and does not necessarily have to fully coincide with the vertical direction. In the structures disclosed above (e.g., structure shown in FIG. 1), upward and downward with respect to the Z-axis direction as referred to in this specification are not limited to upward and downward with respect to the vertical direction. For example, the X-axis direction may be the vertical direction. Alternatively, the Y-axis direction may be the vertical direction.

Exemplary descriptions are given above. In addition to the elements and methods (manufacturing processes) described to illustrate the techniques of this disclosure, one skilled in the art would recognize the potential for a wide variety of combinations and substitutions. The present disclosure encompasses all substitutions, modifications, and variations within the scope of the disclosure including the claims.

### REFERENCE SIGNS LIST

10) semiconductor device
11) semiconductor substrate
11r) second surface
11u) first surface
12) insulation layer
12r) second surface
12u) first surface
13) semiconductor layer
13a) drift region
13r) second surface
13u) first surface
21) buffer region
22) drain region
23) body region
23a) channel region
24) source region
25) contact region
31) gate insulating film
32) gate electrode
41) trench
411) first inner wall
412) second inner wall
413) third inner wall
414) fourth inner wall
42) insulation film
421) first insulation film
422) second insulation film
423) third insulation film
424) fourth insulation film
43) embedded electrode
43r) second surface
43u) first surface
431) first side surface
432) second side surface
433) third side surface
434) fourth side surface
51, 52, 53, 54) terminal
61, 62, 63, 54, 65) interconnecting member
L1) length
T1, T2, T3, T4) film thickness
W1) width
W2) interval
W3) width

1. A semiconductor device comprising:
a semiconductor layer including a surface;
a source region and a drain region arranged on the surface and separated from each other in a first direction as viewed in a thickness-wise direction orthogonal to the surface;
a channel region formed on the surface between the source region and the drain region, the channel region being adjacent to the source region;
a gate electrode arranged on the channel region with a gate insulating film disposed in between;
a trench formed between the source region and the drain region;
an insulation film arranged on inner walls of the trench; and
an embedded electrode arranged in the trench and surrounded by the insulation film.

2. The semiconductor device according to claim 1, wherein the trench extends in the first direction where a direction orthogonal to both the thickness-wise direction and the first direction is a second direction.

3. The semiconductor device according to claim 2, further comprising:
a buffer region in which the drain region is formed,
wherein an end of the trench located toward the drain region is in contact with the buffer region.

4. The semiconductor device according to claim 2, further comprising:
a buffer region in which the drain region is formed,
wherein an end of the trench located toward the drain region is separated from the buffer region.

5. The semiconductor device according to claim 2, further comprising:
a buffer region in which the drain region is formed,
wherein an end of the trench located toward the drain region overlaps the buffer region as viewed in the second direction.

6. The semiconductor device according to claim 2, wherein an end of the trench located toward the source region is in a same position as an end of the gate electrode located toward the drain region as viewed in the thickness direction.

7. The semiconductor device according to claim 2, wherein an end of the trench located toward the source region is closer to the drain region than the gate electrode as viewed in the thickness-wise direction.

8. The semiconductor device according to claim 2, wherein an end of the trench located toward the source region overlaps the gate electrode as viewed in the thickness-wise direction.

9. The semiconductor device according to claim 2, wherein an end of the trench located toward the source region is in contact with the channel region.

10. The semiconductor device according to claim 2, wherein the embedded electrode does not overlap the gate electrode as viewed in the thickness-wise direction.

11. The semiconductor device according to claim 2, wherein, as viewed in the thickness-wise direction, a first film thickness of the insulation film arranged between the embedded electrode and one of the inner walls of the trench in the first direction is greater than a second film thickness of the insulation film arranged between the embedded electrode and one of the inner walls of the trench in the second direction.

12. The semiconductor device according to claim 11, wherein the first film thickness is greater than a thickness of the embedded electrode in the second direction.

13. The semiconductor device according to claim 2, wherein
the trench is one of trenches, and
the trenches are spaced apart from one another in the second direction.

14. The semiconductor device according to claim 13, wherein an interval between two of the trenches adjacent to each other in the second direction is greater than a width of one of the two trenches in the second direction.

15. The semiconductor device according to claim 13, wherein an interval between two of the trenches adjacent to each other in the second direction is less than a width of one of the two trenches in the second direction.

16. The semiconductor device according to claim 1, further comprising:
a semiconductor substrate; and
an insulation layer arranged on the semiconductor substrate,
wherein the semiconductor layer is arranged on the insulation layer.

17. The semiconductor device according to claim 16, wherein the trench extends through the semiconductor layer from the surface of the semiconductor layer to the insulation layer.

18. The semiconductor device according to claim 16, wherein the embedded electrode is in contact with the insulation layer.

19. The semiconductor device according to claim 1, further comprising:
an interconnecting member that connects the embedded electrode to the source region.

20. The semiconductor device according to claim 1, further comprising:
an interconnecting member that connects the embedded electrode to the gate electrode.
